(19) United States
(12) Patent Application Publication
(10) Pub. No.: US 2005/0054158 A1
(43) Pub. Date: Mar. 10, 2005

(54) BULK CONTACT MASK PROCESS

(75) Inventors: Rama Divakaruni, Ossining, NY (US); Rolf Weis, Dresden (DE)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignees: INTERNATIONAL BUSINESS MACHINES CORPORATION, Armonk, NY (US); INFINEON TECHNOLOGIES NORTH AMERICA CORP, San Jose, CA (US)

(21) Appl. No.: 10/605,087

(22) Filed: Sep. 8, 2003

(51) Int. Cl. H01L 21/8234; H01L 21/8244; H01L 21/8242

(52) U.S. Cl. 438/246; 438/243; 438/389

(57) ABSTRACT

In vertical transistor trench DRAM arrays, the problem of pinching off the transistor bodies in the P-well is addressed by etching a set of trenches between the DRAM cell trenches down to a level below the buried straps, thus blocking the depletion regions from the buried straps from meeting. The trench structure contains conductive material that forms a conductive path from the bodies of the vertical transistors to the lower portion of the P-well.

### BACKGROUND OF INVENTION

The field of the invention is that of integrated circuits containing DRAM arrays with closely-spaced trench capacitors.

In the field of trench DRAMS, workers are constantly striving to pack more cells in a given area. The use of a vertical transistor instead of a planar transistor was an important step in shrinking the transverse dimensions of the cells, though at the cost of the expensive etching process to form the deep trenches, now about 8 microns deep.

As those skilled in the art are aware, the vertical trench transistor has its gate formed in the trench and its body in a well (typically a P-well) formed in the bulk silicon.

At the bottom of the vertical transistor body, a buried strap, which is an N-type doped region of the substrate formed by outdiffusion from material inside the trench, creates a depletion region in the P-well. When the capacitor at the bottom of the cell is charged, the diffusion region increases in extent.

The dopant concentration in P-wells is low, in an attempt to reduce leakage of the charge stored in the cell capacitor. Unfortunately, the low dopant concentration increases the length of the depletion region.

The foregoing circumstance, together with the reduced distance between cells resulting from the increase in cell packing density has meant that the depletion regions from adjacent cells can overlap, effectively pinching off the transistor bodies above them.

This, in turn, means that the transistors have floating bodies and therefore suffer from the effects of those floating bodies, such as reduced drive, which, in turn, reduces the amount of charge stored in the capacitor.

It would be highly desirable to construct a DRAM that has increased packing density without the undesirable effects mentioned above.

### SUMMARY OF INVENTION

The invention relates to a trench-capacitor, vertical transistor DRAM array that has an insulating structure placed between adjacent cells.

A feature of the invention is etching a set of trenches placed between DRAM cells and extending down below the level of the buried straps in the DRAM cells.

Another feature of the invention is the blockage of a horizontal path between adjacent buried strap diffusions.

Another feature of the invention is the provision of a vertical conductive path from the level of the transistor bodies to below the buried strap diffusions.

### BRIEF DESCRIPTION OF DRAWINGS

FIG. 1 shows a cross section of a portion of a DRAM array, showing the close approach of buried strap outdiffusion regions.

FIG. 2 shows an isolating trench etched into the region shown in FIG. 1.

FIG. 3 shows the isolating trench after deposition and recession of a nitride liner.

FIG. 4 shows the region after deposition and recession of boron-doped poly to the level of the transistor bodies of the vertical cell transistors.

FIG. 5 shows the completed structure, blocking horizontally and connecting vertically.

FIG. 6 shows a top view of the layout of the trenches.

### DETAILED DESCRIPTION

Referring to FIG. 6, there is shown a top view of a portion of a DRAM array. Deep trenches (DT) 62 contain the capacitor and vertical transistor of the cell. Interconnections to bit lines and word lines will be added at a later time.

Between trenches 62, there are blocking/bulk contact trenches 65 that perform the dual functions of blocking the spread of depletion regions from the buried straps and also establishing a vertical conductive path extending from the transistor bodies down below the buried straps.

Trenches 62 are defined by a mask, referred to as the DT separation mask, that inevitable will not be perfectly aligned with the DT mask. There will, therefore, be a difference in distance between the vertical contact formed according to the invention and the body of the vertical transistors on the left and right. Preferably, the contact trenches are made as small as possible (having the minimum lithographic dimension available in the current process) so that the misalignment is a relatively small fraction of the total distance between trenches.

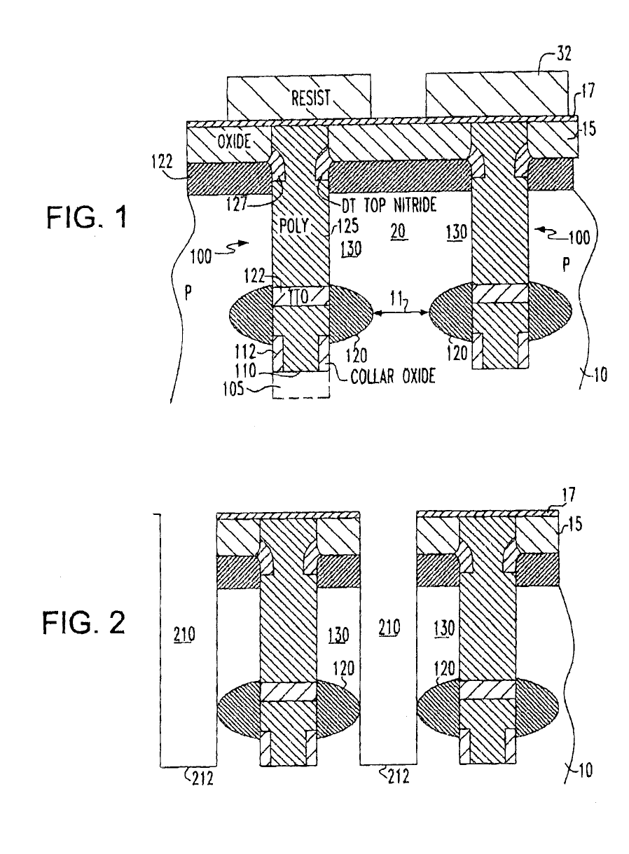

FIG. 1 shows a cross section of a portion of the array perpendicular to line 1-1 of FIG. 6. In this figure, two DRAM cells 100 are shown, with a capacitor 105 at the bottom of the trench, shown schematically by dotted line 105, and a vertical transistor placed above the capacitor. The capacitor 105 is only shown schematically in the drawing as its structure is conventional and not relevant to the practice of the present invention.

The portion of the semiconductor wafer (e.g. silicon) in which the transistors are located is a P-well 20, doped to a conventional concentration with p-type dopant. The bulk of the wafer is doped N-type, the transition between P-type and N-type being located below buried straps 120, at a height where collar oxide 112 insulates the capacitor from the bulk silicon.

The transistors are bounded vertically on the bottom by a buried strap 120 that forms the drain and on the top by a horizontal diffusion 122 that forms the source and also the contact to the bit line (added in a later step). Upper nitride spacers 127, together with the gate oxide, separate the transistor gate 125 from the source 122.

At the bottom of the trench, capacitor 105 has been formed with center electrode 110. At the level shown, electrode 110 is insulated from the bulk silicon by collar oxide 112. Above oxide 112, the material of the center electrode has formed the interior portion of the buried strap and diffused dopant into the bulk silicon to form drain 120. Trench top oxide (TTO) 122 separates the center electrode from the transistor gate 125.

Drains 120 are separated by distance 11. Nominally, the horizontal extent of drains 120 is 1F, where F is the symbol for the minimum lithographic distance, nominally 100 nm, say. In this case, distance 11 is also 1F, which is the amount allocated for the isolation trenches to be built.

Referring back to FIG. 6, it can be seen that the trenches 210 have a width about equal to the separation from the adjacent deep trench, which is also the length of the drains (1F according to the example). Along 1-1 (vertical in FIG. 6), the length is considerably longer, nominally 2×, to provide better overlap with the isolation trench area between the active area lines.

The overall process sequence may be summarized as: Form DRAM cells containing trench capacitors and vertical transistors connected by buried straps.

Etch through top oxide over the region between DRAM cells.

Form a second set of trenches (contact trenches) placed between DRAM cells and extending down below the buried strap depth (using a silicon etching process selective to oxide).

Form an oxide liner in the second set of trenches.

Form a nitride liner in the second set of trenches.

Reactive ion etch (RIE) the trenches directionally, removing the nitride and oxide liner on the bottom.

Fill the second trenches with resist; recess the resist.

Etch the exposed portion of the nitride spacer selective to oxide.

Perform nitridation on the upper portion above the nitride liner Deposit boron-doped poly in the trenches.

Recess the poly.

Diffuse boron into the P-well through the upper portion of the trench (above the nitride liner).

Fill the upper part of the trench with Nitride.

Oxide etch on the wafer surface, exposing the top of the DRAM cells.

W/WN Gate Layers on the wafer surface.

Cap Nitride

FIG. 2 shows the area after the trench has been etched. A resist 32, shown in FIG. 1, has been patterned and top oxide 15 has been etched in an oxide etch.

Next, a timed reactive ion etch (RIE), performed for example in an Applied Materials 5000 tool using conventional chemistry has performed a highly directional etching step down to a level below drains 120, forming trench aperture 210. The chemistry does not attack oxide to any significant degree, so that top oxide 15 serves as a hardmask in this operation. The depth of aperture 210 is nominally enough to get down below the transistor body, compared with the nominal depth of the deep trench in the DRAM cell of 8 microns.

In operation, current will flow between the body region 130 of the P-well above the drains and the bottom of trench 210 below the drains. The path for the current is completed through the bias supply that biases P-well 20. Thus, the transistor bodies 130 will not be floating, regardless of the length of the depletion regions associated with drains 120.

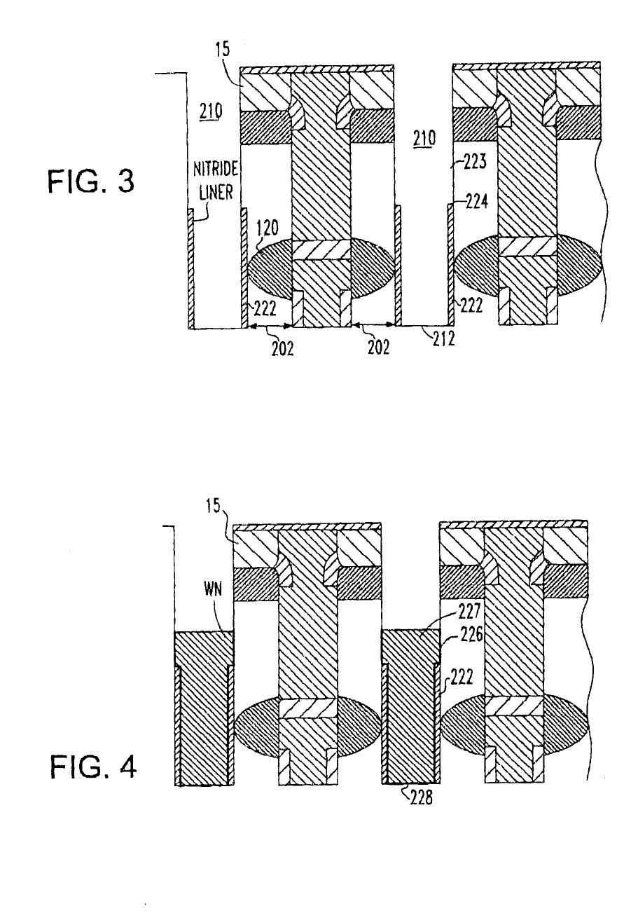

FIG. 3 shows the area after a number of steps, including: Oxidizing (preferably thermally) the interior surface of trench 210 to a conventional thickness to passivate the surface.

A liner of nitride (Si₃N₄) is deposited by CVD to a conventional thickness.

The nitride is etched with a directional RIE step, so that the material on bottom 212 is selectively removed without substantially affecting the nitride 222 on the vertical surfaces. In the final structure, there will be current flow through the bottom surface 212.

The trench is filled with resist that is recessed to a nominal depth of the middle of the body of the vertical transistors, denoted with numeral 224.

The nitride 222 on the interior surface of the trench is stripped above depth 224, illustratively with hot phosphoric acid, to leave the oxide on surfaces 223.

The resist is stripped and the trench interior is subject to a step of nitridation, in which a gas containing nitrogen that reacts with the material in the trench is introduced at a conventional temperature such that the oxide on surfaces 223 is converted to nitride 226 (or a layer of nitride is deposited) to a nominal thickness. The gas thickens the nitride 222 slightly and deposits a layer 228 at the bottom of trench 210. The nitridation is similar to that done in the buried strap interface and does not hinder conduction significantly, but serves to passivate the silicon in that area.

The trench is filled with boron-doped poly 227 (doped P⁺) that is recessed to a nominal depth above the top of nitride liner 222.

Subsequent high-temperature steps will diffuse boron into the transistor body regions 130 to establish a relatively low-resistance path from the body 130 to the lower level.

The presence of the outdiffusion 230 will affect the threshold of the vertical transistors. Preferably, the initial doping of the vertical transistors is set such that the final threshold is correct.

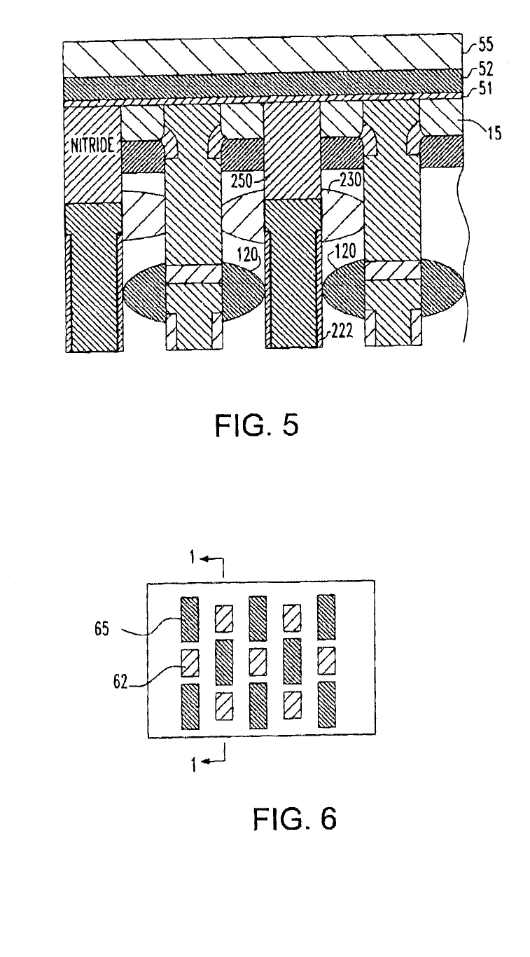

FIG. 5 shows the area after the steps of nitride divot fill, in which a conformal layer of nitride is deposited that fills the top of the contact trenches and also penetrates laterally to fill any “divots” resulting from previous etching steps.

After conventional chemical-mechanical polishing to remove the excess nitride, a layer of Tungsten Nitride 51 and Tungsten 52, followed by a Nitride cap layer 55 is put down. Layers 51 and 52 will be patterned to form the word lines at any convenient time. The bit lines will also be formed by conventional processes at any convenient time.

While the invention has been described in terms of a single preferred embodiment, those skilled in the art will recognize that the invention can be practiced in various versions within the spirit and scope of the following claims.

1. A method of forming an array of dram cells comprising the steps of:
forming trench capacitors in a first set of trenches in a semiconductor substrate;
forming vertical transistors above said trench capacitors in said first set of trenches, said capacitors and vertical transistors being connected by a set of buried straps formed at a strap depth in a layer of said semiconductor substrate;
forming a second set of trenches in said semiconductor substrate, said second set of trenches being disposed between members of said first set of trenches, said second set of trenches having an insulating liner at said strap depth, whereby potential paths between adjacent buried straps in said first set of trenches are blocked from forming; and
said second set of trenches contain a vertical conductive path connecting body regions in said semiconductor substrate at a level above said strap depth and bias regions in said semiconductor substrate at a level below said strap depth.

2. A method according to claim 1, further comprising the steps of:
etching said trenches within upper and lower regions of a well, such that said upper and lower regions of said well are connected by a conductive path.

3. A method according to claim 1, further comprising the steps of:
forming a liner on the interior surfaces of said second set of trenches; and
etching said liner on the bottom surface of said second set of trenches, so that said conductive path extends to said substrate through said bottom surface.

4. A method according to claim 2, further comprising the steps of:
forming a liner on the interior surfaces of said second set of trenches; and
etching said liner on the bottom surface of said second set of trenches, so that said conductive path extends to said substrate through said bottom surface.

5. A method according to claim 1, further comprising the steps of:
filling said second set of trenches with a conductive material and diffusing said conductive material into said substrate.

6. A method according to claim 2, further comprising the steps of:
filling said second set of trenches with a conductive material and diffusing said conductive material into said substrate.

7. A method according to claim 3, further comprising the steps of:
filling said second set of trenches with a conductive material and diffusing said conductive material into said substrate.

8. A method according to claim 4, further comprising the steps of:
filling said second set of trenches with a conductive material and diffusing said conductive material into said substrate.

9. A method according to claim 1, in which said substrate is silicon and further comprising the steps of nitriding the interior surface of said second set of trenches before said step of filling said second set of trenches with a conductive material.

10. A method according to claim 2, in which said substrate is silicon and further comprising the steps of nitriding the interior surface of said second set of trenches before said step of filling said second set of trenches with a conductive material.

11. A method according to claim 3, in which said substrate is silicon and further comprising the steps of nitriding the interior surface of said second set of trenches before said step of filling said second set of trenches with a conductive material.

12. A method according to claim 4, in which said substrate is silicon and further comprising the steps of nitriding the interior surface of said second set of trenches before said step of filling said second set of trenches with a conductive material.

13. A method according to claim 1, in which said second set of trenches are formed with a transverse dimension that is the minimum distance permitted by lithography.

14. An integrated circuit including an array of DRAM cells comprising:
an array of trench capacitors in a first set of trenches in a semiconductor substrate;
said array of DRAM cells further comprising vertical transistors above said trench capacitors in said first set of trenches, said capacitors and vertical transistors being connected by a set of buried straps formed at a strap depth in a layer of said semiconductor substrate;
a second set of trenches in said semiconductor substrate, said second set of trenches being disposed between members of said first set of trenches, said second set of trenches having an insulating liner at said strap depth, whereby potential paths between adjacent buried straps in said first set of trenches are blocked from forming; and
said second set of trenches containing a vertical conductive path connecting body regions in said semiconductor substrate at a level above said strap depth and bias regions in said semiconductor substrate at a level below said strap depth.

15. An integrated circuit according to claim 14, in which:
said second set of trenches extend between upper and lower regions of a well and have a liner on the interior surfaces thereof, such that said upper and lower regions of said well are connected by a conductive path that is isolated from intermediate levels of said well.

16. An integrated circuit according to claim 14, in which said semiconductor substrate is silicon and said conductive path passes through a nitrided silicon surface above said liner.

17. An integrated circuit according to claim 14, in which said semiconductor substrate is silicon and said conductive path passes through a nitrided silicon surface above said liner.
